(19) United States
(12) Patent Application Publication
(10) Pub. No.: US 2024/0405103 A1
(43) Pub. Date: Dec. 5, 2024

(54) METHOD FOR PRODUCING A SEMICONDUCTOR DEVICE COMPRISING A SIDE GATE

(71) Applicant: COMMISSARIAT A L'ENERGIE ATOMIQUE ET AUX ENERGIES ALTERNATIVES, Paris (FR)

(72) Inventors: Hamza SAHIN, Grenoble Cedex 09 (FR); Benoît BERTRAND, Grenoble Cedex 09 (FR); Heimanu NIEBOJEWSKI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/678,118

(22) Filed: May 30, 2024

(30) Foreign Application Priority Data
May 31, 2023 (FR) 2305394

(51) Int. Cl. H01L 29/66; H01L 29/423

(52) U.S. Cl. CPC H01L 29/66977; H01L 29/4236; H01L 29/66545

(57) ABSTRACT

A method for producing a lateral gate for a semiconductive device, comprising: etching of trenches depositing an electrode laver on the flank of the trenches, and a dielectric material filling. Advantageously, the lateral gate electrostatically controls a distribution of the charge carriers in a metal-oxide-semiconductor (MOS)-type structure, in particular for spin qubit applications.

### TECHNICAL FIELD

The present invention relates to the field of microelectronics and quantum electronics, in particular. It has, for example, a particularly advantageous application in producing lateral gates in quantum bit (or qubit) quantum devices, in particular for devices based on spin qubit architectures.

### PRIOR ART

The semi-conductive devices implemented in quantum architectures based on controlling and detecting the state of quantum dots typically require very high interface qualities to avoid that the distribution of charges at the quantum dots is not impacted by the presence of charge traps at said interfaces.

An approach developed in this context consists of using heterostructures, which are typically stacks of silicon and silicon-germanium layers, in order to benefit from an interface without defects obtained by epitaxy. A disadvantage of this approach is that the thermal budget which is acceptable for these heterojunction structures is relatively low. This imposes additional stresses and/or limitations for the industrial manufacture of such devices, in particular in terms of modifications and of adapting technological methods to be implemented. The integration of such devices in SOC (“System On Chip”)-type complete embedded systems is also more limited.

Another solution consists of preserving a conventional metal-oxide-semiconductor (MOS)-type conventional structure, easily integrable and having well-known and advantageous properties. The document “Temperature-Dependent Characteristics and Electrostatic Threshold Voltage Tuning of Accumulated Body MOSFETs, A. B. M. Hasan Talukder et al., IEEE Transactions on Electron Devices, Vol. 69, 8 (2022)” has a study of the performance of a low-temperature MOSFET. The MOSFET presented in this document is based on the formation of one single lateral gate surrounding the walls of an active zone located projecting from the substrate. This lateral gate makes it possible to modulate the electrostatic environment at the active zone of the semiconductive device, without for all that, enabling an electrostatic control of charges far from the interfaces. In addition, manufacturing such a device is not directly industrially transposable.

For quantum applications, in particular, a controlled industrial manufacture, satisfying the required quality requirements, is a significant challenge for developing these technologies.

An aim of the invention is to meet this need, and to overcome at least some of the disadvantages of known solutions.

In particular, an aim of the invention is an industrialisable method for producing a lateral gate for a semiconductive device. Another aim of the invention is a lateral gate semiconductive device.

Other aims, features and advantages of the present invention will appear upon examining the description below and the accompanying drawings. It is understood that other advantages can be incorporated.

### SUMMARY

To achieve this aim, according to an embodiment, a method for producing a device is provided, comprising a metal-oxide-semiconductor (MOS)-type structure formed from a stack comprising successively, in a direction z, a support layer, an insulating layer and a semiconductive layer. The device further comprises first and second lateral gates electrically insulated from one another, and configured to electrostatically control a distribution of charge carriers in the semiconductive layer perpendicularly to the direction z. The method comprises:
a formation of at least one trench passing through the semiconductive layer and extending up to into the insulating layer, said trench formation thus defining an active zone of the semiconductive layer, and exposing edges of said active zone,
a formation of a first dielectric barrier on each exposed edge of the active zone, said first dielectric barrier partially forming a flank of said at least one trench,
a deposition of an electrode layer on the flank of the at least one trench, and preferably on a bottom of the at least one trench, said electrode layer having at least one so-called lateral portion on the flank of the at least one trench, said at least one lateral portion forming first and second lateral gates, and preferably a so-called basal portion on the bottom of the at least one trench,
a filling of the at least one trench by a dielectric material.
a formation of a second dielectric barrier on an upper face of the active zone and on an upper end of the lateral gate bordering the active zone,
a formation of a vertical gate on the second dielectric barrier, above the active zone, configured to electrostatically control the distribution of charge carriers in the semiconductive layer in the direction z, so as to obtain the metal-oxide-semiconductor-type structure.

The steps of this method are fully industrially controllable. The method thus guarantees a manufacturing quality which is compatible with the required specifications for MOS devices comprising a lateral gate, in particular for quantum MOS devices comprising a lateral gate. It is further possible to integrate the manufacture of the lateral gate MOS device in a vaster method flow, typically comprising the formation of different metal and interconnecting levels. The method according to the invention thus offers an improved solution for manufacturing lateral gate MOS devices.

Another aspect of the invention relates to such a lateral gate MOS device, typically comprising a lateral gate formed by the method according to the invention. In particular, such a device comprises a metal-oxide-semiconductor-type structure formed from a stack comprising successively, in a direction z, a support layer, an insulating layer and a semiconductive layer, wherein an active zone is defined; the device further comprises a first lateral gate on a first edge of the active zone, configured to electrostatically control a distribution of charge carriers in the semiconductive layer perpendicularly to the direction z, and a vertical gate above the active zone, configured to electrostatically control the distribution of charge carriers in the semiconductive layer in the direction z.

Advantageously, the device comprises a second lateral gate on a second edge of the active zone, configured to electrostatically control a distribution of charge carriers in the semiconductive layer perpendicularly to the direction z, said second lateral gate being electrically insulated with respect to the first lateral gate. The vertical gate is electrically insulated with respect to the first and second lateral gates. The device further comprises a dielectric material encapsulating said first and second lateral gates.

Thus, the electrostatic control of the distribution of charge carriers in the semiconductive layer is improved. In particular, this makes it possible to avoid interactions between the distribution of charges and the potentially awkward interfaces. It is thus possible to confine the charges within the active zone of the device, far from the interfaces.

### BRIEF DESCRIPTION OF THE FIGURES

The aims, objectives, as well as the features and advantages of the invention will best emerge from the detailed description of an embodiment of the latter which is illustrated by the accompanying drawings below, wherein:

FIGS. 1 to 6 schematically illustrate, as a cross-section, steps of manufacturing a lateral gate of a semiconductive device, according to an embodiment of the present invention.

FIGS. 7A and 8A schematically illustrate, as a cross-section, steps of manufacturing two lateral gates of a semiconductive device, according to another embodiment of the present invention. FIGS. 7B and 8B schematically illustrates, in perspective, the manufacturing steps illustrated in corresponding FIGS. 7A and 8A.

FIGS. 9, 10, 11 schematically illustrate, in perspective, steps of manufacturing vertical gates and source and drain regions, according to a first embodiment of the present invention.

FIGS. 12, 13 schematically illustrate, in perspective, steps of manufacturing vertical gates and source and drain regions, according to a second embodiment of the present invention. The drawings are given as examples and are not limiting of the invention. They constitute principle schematic representations intended to facilitate the understanding of the invention and are not necessarily to the scale of practical applications. In particular, in the principle diagrams, the thicknesses and/or the dimensions of the different layers, patterns and raised parts are not representative of reality. For reasons of clarity, all of the alphanumerical references are not systematically revisited from one figure to another. It is understood that the elements already described and referenced, when they are reproduced on another figure, typically have the same alphanumerical references, even if these are not explicitly mentioned. A person skilled in the art will identify, without difficulties, one same elements reproduced in different figures.

### DETAILED DESCRIPTION

Before starting a detailed review of embodiments of the invention, optional features are stated below, which can optionally be used in association or alternatively:

According to an example, the device is a quantum device and the distribution of charge carriers is localised at a quantum dot or a quantum box. The quantum boxes are typically formed by way of an electrostatic confinement (via the application of a voltage on the gates) and of a structural confinement (in the topSi thin layer, typically).

According to an example, the first and second lateral gates and the vertical gate are metal or conductive at cryogenic temperatures less than or equal to 50 mK. The lateral and vertical gates are thus functional, even at low temperature, typically for operating temperatures of a quantum device. Contrary to gates made of a doped or highly doped semiconductive-type material, gates made of a metal material are not sensitive to the freezing of carriers which occurs at low temperature. The metal lateral and vertical gates thus remain functional at low temperature.

According to an example, the semiconductive layer has, projecting in the direction z, a shape comprising a first and a second closed contour which share a common section. According to an example, the active zone is located in said common section, the first and second lateral gates being located respectively inside the first and second closed contours. According to an example, the device further comprises secondary gates above the semiconductive layer on either side of the common section, said secondary gates being configured to electrically insulate source and drain regions located at the ends of the common section.

According to an example, the device comprises several vertical gates, certain vertical gates covering, at least partially, the active zone, and certain other vertical gates not covering the active zone.

According to an example, the device comprises at least one charge reservoir on either side of the active zone, flush with the vertical gate.

According to an example, the method further comprises, before formation of the second dielectric barrier, a partial etching of the electrode layer lateral portion, configured to lower the upper end of the lateral gate under the plane passing through the upper face of the active zone. The upper end of the lateral gate is thus recessed from the vertical gate. This minimises the interaction, for example, capacitive, between the two gates.

According to an example, the method comprises, after filling the at least one trench and before formation of the second dielectric barrier, a planarisation configured such that the upper end of the lateral gate is flat parallel to a plane passing through the upper face of the active zone. This facilitates the integration of the device.

According to an example, the deposition of the electrode layer is done also on a bottom of the at least one trench, said electrode layer thus having a basal portion on the bottom of the at least one trench in contact with the lateral portion on the flank of the at least one trench, said method further comprising a formation of a contact via through the dielectric material configured to electrically contact the basal portion of the electrode layer. This facilitates the integration of the device, in particular in a method flow comprising so-called “back end” steps, aiming to form different metal and interconnecting levels.

According to an example, the formation of at least one trench is configured to form a first trench of a first side of the active zone and a second trench of a second side of the active zone, separated from the first trench, and the deposition of the electrode layer forms, respectively in the first and second trenches, first and second lateral gates, not electrically connected to one another. This makes it possible to more finely control a position of the distribution of charge carriers in the semiconductive layer perpendicularly to the direction z, by typically applying bias voltages to the first and second lateral gates. It is also possible, in a configuration where the vertical gate is divided into two parts facing one another, to manage an exchange of charge carriers under the two parts.

According to an example, the semiconductive layer has a shape comprising a first and a second closed contour which share a common section, and the active zone is located in the common section, the first and second lateral gates being located respectively inside the first and second closed contours. The semiconductive layer typically has an eight shape, making it possible to insulate the first and second lateral gates in the closed contours.

According to an example, the method further comprises an etching step, configured to cut the semiconductive layer on either side of the common section, so as to electrically insulate source and drain regions located at the ends of the common section.

According to an example, the method further comprises, during the formation of the vertical gate above the active zone, a formation of secondary gates above the semiconductive layer on either side of the common section, said secondary gates being configured to electrically insulate source and drain regions located at the ends of the common section.

According to an example, the at least one lateral gate comprises first and second lateral gates not electrically connected to one another.

According to an example, the vertical gate comprises first and second parts not electrically connected to one another and partially covering the active zone. These first and second parts can be used for controlling and detecting qubits.

According to an example, the device is a quantum device and the distribution of charge carriers is localised at a quantum dot.

According to an example, the device comprises a metal-oxide-semiconductor-type structure and comprises at least one lateral gate produced by a production method according to the invention.

According to an example, the formation of the electrode layer is done by conform deposition on the flanks and the bottom of the at least one trench. Typically, the flank of the first trench runs alongside the second edge of the active zone. The bottom of the trenches is located within the insulating layer, under a plane passing through the lower face of the active zone. The first and second lateral gates are therefore located against opposite lateral flanks, i.e. opposite the active zone. The active zone is thus flanked, on either side, by the first and second lateral gates. These first and second lateral gates extend, preferably up to within the insulating layer, under the active zone. The first and second lateral gates respectively comprise at least first and second lateral portions, and preferably, respectively, first and second basal portions. The first and second lateral gates thus each have an L-shaped profile, cross-sectional along the plane zy. The basal portions facilitate the electrical contacting of the first and second lateral gates. The extension of the lateral portions in the insulating layer makes it possible to best manage the electrostatic field of the first and second lateral gates. This makes it possible, in particular, to avoid forces interfering with the electrostatic field. In any case, the first and second lateral gates are electrically independent from one another.

According to an example, the electrode layer is chosen as metal-based, for example, titanium.

According to an example, the dielectric filling material is chosen as SiO2-based.

Unless incompatible, it is understood that all of the optional features above can be combined so as to form an embodiment which is not necessarily illustrated or described. Such an embodiment is clearly not excluded from the invention. The features and the advantages of an aspect of the invention, for example, the device or the method, can be adapted mutatis mutandis to the other aspect of the invention.

The invention generally relates to a method for manufacturing a lateral gate for a semiconductive device, and on such a device equipped with a lateral gate. A semiconductor device according to the invention typically comprises a semiconductive layer, wherein charge carriers or quantum states pass through. For example, and in a non-limiting manner, this semiconductive layer can thus form a transistor channel, or be integrated in a spin qubit architecture for quantum bit (qubit) quantum devices.

It is specified that, in the scope of the present invention, the terms “on”, “surmounts”, “covers”, “underlying”. “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer covers at least partially the second layer by being either directly in contact with it, or by being separated from it by at least one other layer or at least one other element.

By a substrate, a film, a layer “with the basis” of a material A, this means a substrate, a film, a layer comprising this material A only or this material A and optionally other materials, for example, doping elements or alloy elements.

By “shape having a closed contour”, this means any geometric shape comprising an uninterrupted edge, such as a circle, a square, a triangle, a star, etc. Preferably, the shape comprises two closed contours having a common side, such as two rectangles having a side in common.

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the embodiment of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of the phases of the method.

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced SAB. A selectivity SA:B of 10:1 means that the etching speed of the material A is 10 times greater than the etching speed of the material B.

A preferably orthonormal system, comprising the axes x, y, z is represented in the accompanying figures. When one single system is represented on one same set of figures, this system applies to all the figures of this set.

In the present patent application, thickness will preferably be referred to for a layer or a film, and of height for a device or a structure. The thickness is taken in a direction normal to the main extension plane of the layer or of the film. Thus, a superficial silicon layer (topSi) typically has a thickness along z. A gate pattern formed on such a superficial layer has a height along z. The relative terms “on”, “surmounts”, “under”, “underlying” refer to positions taken in the direction z. A “lateral” dimension corresponds to a dimension in a direction of the plane xy. By a “lateral” extension or “laterally”, this means an extension in one or more directions of the plane xy.

An element located “in vertical alignment with” or “to the right of” another element means that these two elements are both located on one same line perpendicular to a plane, wherein a lower or upper face of a substrate mainly extends, i.e. on one same line oriented vertically in the figures, as a cross-section.

The terms “substantially”, “about”, “around” mean within 10%, and preferably within 5%. Moreover, the terms “between . . . and . . . ” and equivalents mean that the limits are included, unless mentioned otherwise.

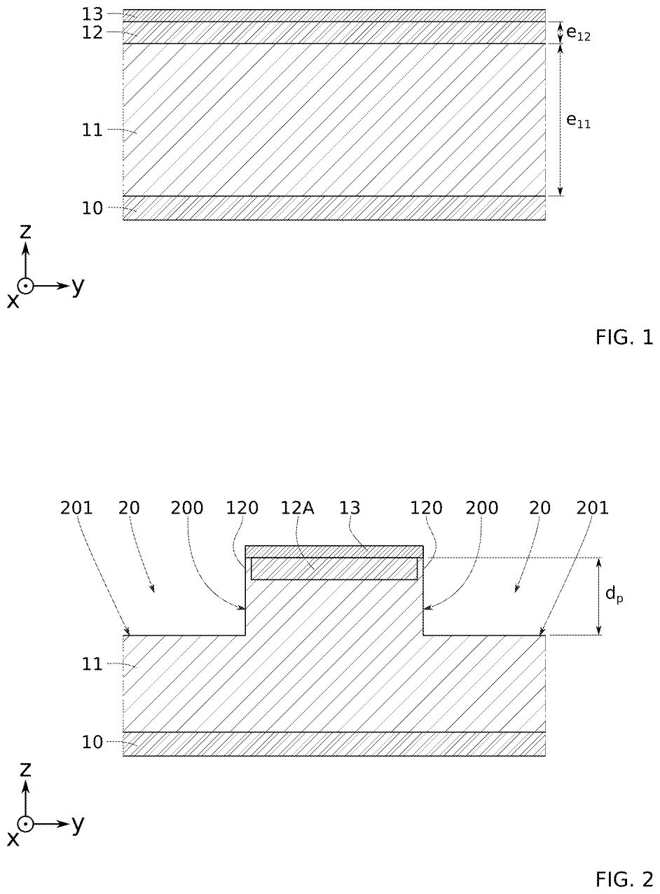

FIGS. 1 to 6 schematically illustrate, as a cross-section, steps of manufacturing a lateral gate of a semiconductive device, according to an embodiment.

As illustrated in FIG. 1, a hard mask deposition 13, for example, alumina-based, is first done on an SOI-type substrate comprising, stacked along z, a support layer 10, typically a so-called “bulk” silicon solid substrate, an insulating layer 11, typically a so-called “BOX” buried oxide layer, and a semiconductive layer 12, for example, a so-called topSi silicon layer. The insulating layer 11 typically has a thickness e11 of around 200 nm to 300 nm. The topSi layer 12 typically has a thickness e12 of around 5 nm to 20 nm.

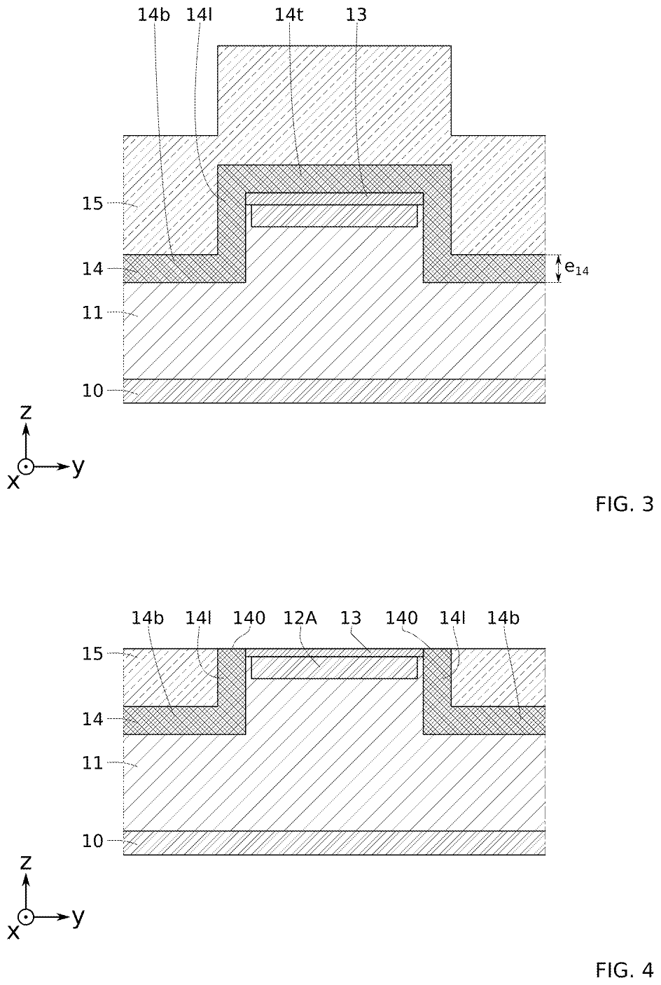

As illustrated in FIG. 2, after definition by lithography of a pattern comprising the active zone 12A of the device, an anisotropic dry etching along z is done. The etching depth dp is chosen so as to form trenches 20 extending up to into the insulating layer 11, through the layer 12 of the stack. The etching depth dp is, for example, around 100 nm. A reactive ionic etching (RIE) or a fluorocarbon species-based plasma etching can be used to successively etch the layers 12 and 11 of the stack. One or more trenches 20 having flanks 200 and one of the bottoms 201 are thus formed. The trenches 20 expose the edges 120 of the semiconductive layer 12. A thermal oxidation is done so as to form a first dielectric barrier on each exposed edge 120 of the active zone 12A As illustrated in FIG. 3, a conform deposition of an electrode layer 14 is first done, for example, by chemical vapour deposition CVD. The layer 14 typically has a thickness e14 of around 10 nm to 20 nm. The layer 14 has, at this stage, basal portions 14b on the bottom of the trenches 20, of the lateral portions 141 on the flank of the trenches 20, and a summit portion 14t on the hard mask 13. The electrode layer 14 is preferably metal material-based, for example, Ti. After conform deposition of the electrode layer 14, a filling of the trenches 20 by a dielectric material 15 is then done. The dielectric layer 15 is typically SiO2-based. The filling can be done usually by high density plasma (HDP)- or of chemical vapour deposition CVD-type conform deposition.

As illustrated in FIG. 4, after filling, a planarisation step, typically by chemical-mechanical polishing CMP, is carried out. This planarisation step aims to remove the excess dielectric material 15 and the summit portion 14t. CMP polishing is typically configured to stop in the hard mask layer 13. The ends 140 of the lateral portions 141 are thus formed. The lateral portions 141 of the electrode layer form a lateral gate around the active zone 12A of the device.

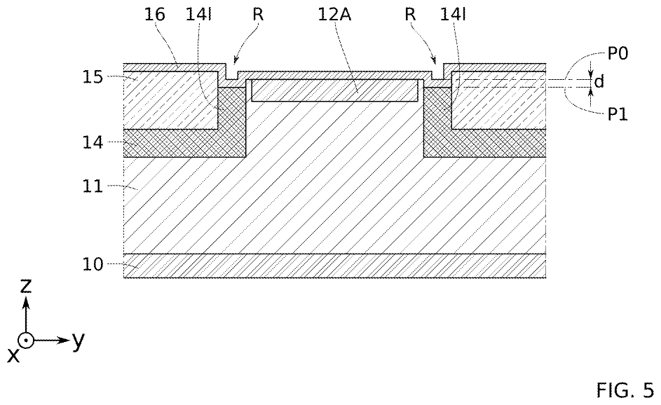

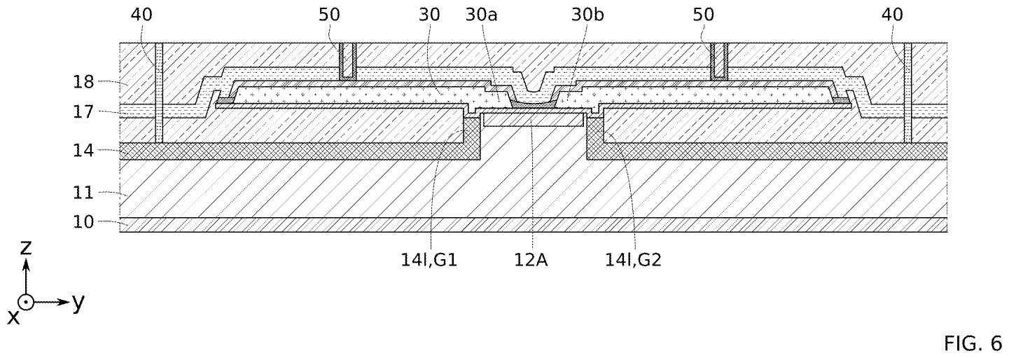

As illustrated in FIG. 5, according to a preferred option, after planarisation, a selective etching of the material of electrode layer with respect to the layer 13 and of the dielectrical material 15 is done, for example, in wet chemistry of the “hot SPM” (Sulfuric Peroxide Mixture) type. A chlorine-based (BCL3+CL2) or fluorine-based (SF6+CHF3) plasma dry etching is also possible, with good selectivity results between the material of the electrode layer and the dielectric material and that of the layer 13. This makes it possible to lower the ends 140 of the lateral portions 141 under the planarisation face. A removal R, typically called “recess”, is thus formed. In particular, the etching is configured to lower the ends 140 under a plane P0 corresponding to the upper face of the active zone 12A. This makes it possible to move away from the ends 140 of the elements subsequently formed on the upper face of the active zone 12A, in particular of the vertical gate subsequently formed on the upper face of the active zone 12A. The interfering capacities between the lateral gate and the vertical gate are thus decreased or removed. According to an example, after recess R, the ends 140 are located substantially in a plane P1 parallel to the plane P0 and distant from the plane P0 of a distance d of between 2 nm and 10 nm, for example, around 5 nm. After formation of the recess R, a second dielectric barrier 16, for example, alumina-based, is formed on the ends 140 and on the surface of the active zone 12A.

According to another option not illustrated, the second dielectric barrier 16 is formed directly on the structure illustrated in FIG. 4, without prior recess R formation. The second dielectric barrier 16 is, in this case, thicker above the active zone 12A.

As illustrated in FIG. 6, one or more vertical gates are then formed, comprising, for example, the second dielectric barrier 16 and/or a so-called high dielectric constant “high k” layer, a conductive layer 30, for example, made of polycrystalline silicon (polySi) or made of metal (TiN). The vertical gate pattern covers at least partially the active zone 12A. It can comprise a first part 30a and a second part 30b not electrically connected to one another, as illustrated in FIG. 6. This type of architecture is typically implemented for controlling and detecting qubits in quantum devices. The vertical gate(s) can be “dummy” or sacrificial gates. Conventionally, after formation of the vertical gate pattern(s), a conform deposition of a contact etch stop layer (CESL) 17, for example made of SiN, can be done. This deposition can be done according to a plasma-enhanced chemical vapour deposition (PECVD) method. A deposition of dielectric material 18, for example, SiO2-based, is then done. This deposition can be done according to a known HDP deposition method or from TEOS (tetraethyl orthosilicate)-type precursors. The layer 18 is then planarised by CMP. Via openings are then made through the layers 18, 17, 15 by successive dry etchings, in vertical alignment with the vertical gates and the portions 141 of the electrode layer. Contact vias 50 are thus formed in a known manner to electrically contact the vertical gates 30a, 30b. Contact vias 40 are thus formed in a known manner to electrically contact the lateral gates 141. The lateral gates 141 can thus be biased independently of the vertical gates 30a, 30b. This makes it possible to position, more precisely, the distribution of charge carriers within the active zone 12A.

According to an embodiment illustrated in more detail below, two lateral gates G1, G2 independent of one another are formed on either side of the active zone 12A. This makes it possible to independently bias these two lateral gates G1, G2. This increases the options for controlling and positioning the distribution of charge carriers within the active zone 12A. According to an option, the lateral gates G1, G2 advantageously make it possible to enhance a qubit exchange between the two vertical gate parts 30a, 30b.

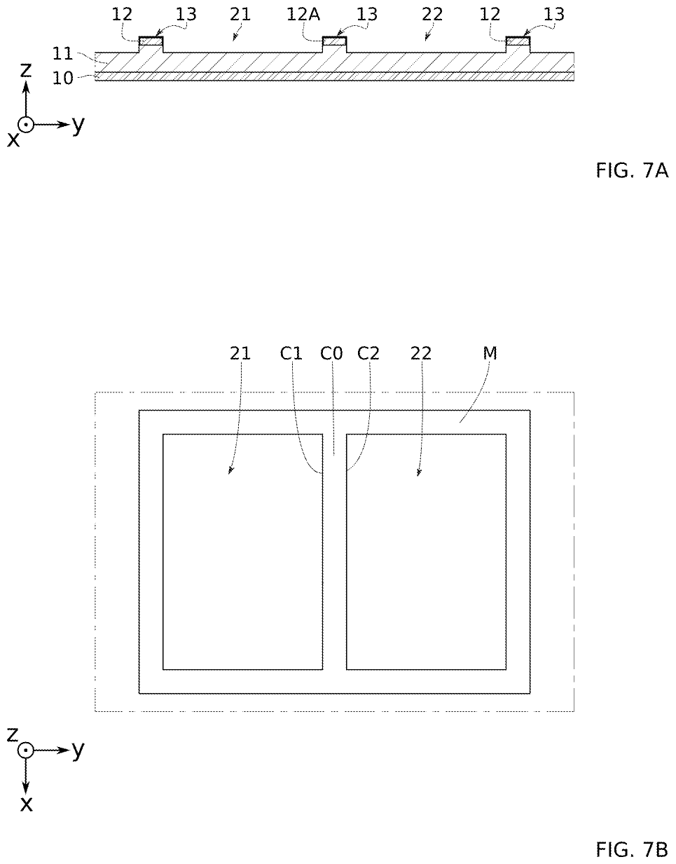

FIGS. 7A, 7B illustrate an eight-shaped pattern M making it possible to produce two lateral gates G1, G2 independent of one another. This pattern M is formed by lithography and etching the semiconductive layer 12 after deposition of the hard mask 13, during the formation of the trenches 21, 22. The pattern M typically comprises two closed contours C1, C2 delimiting two trenches 21, 22 without communication between one another. The active zone 12A is typically located at the central bar C0 of the eight illustrated in the figures.

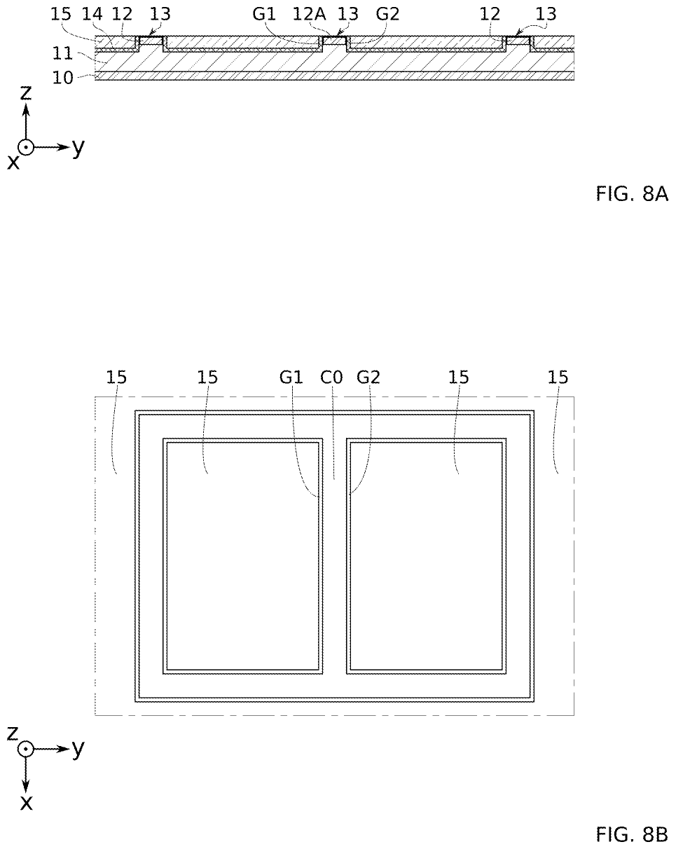

As illustrated in FIGS. 8A, 8B, the electrode layer 14 is deposited in the trenches 21, 22 and a dielectric material filling 15 is done, as above. After planarisation, two independent lateral gates G1, G2 are formed on either side of the active zone 12A.

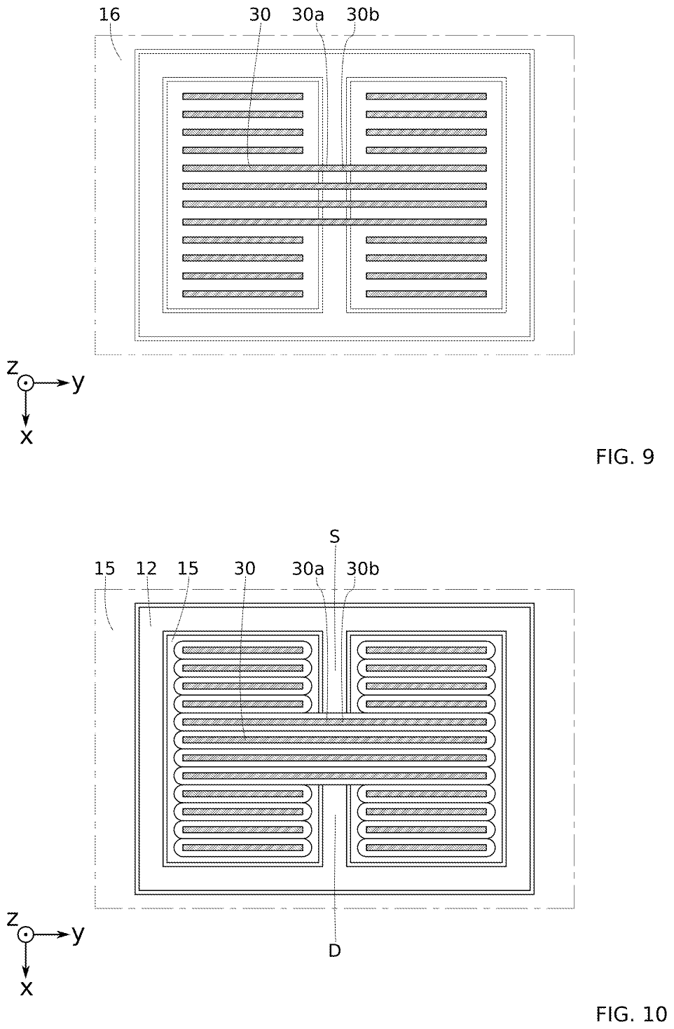

As illustrated in FIGS. 9 and 10, after deposition of the second dielectric barrier 16, vertical gates 30 are formed above the active zone 12A. In the figures, four vertical gates 30a and four vertical gates 30b, mounted on the active zone 12A, are illustrated. After removal of the exposed parts of the second dielectric barrier 16, the eight-shaped structured layer 12 is exposed. Source S and drain D regions, or reservoirs for quantum devices, are formed on or in the layer 12, for example, by epitaxy on either side of the active zone along x. These source and drain regions S, D, can be doped in situ during epitaxy. They can be phosphorus doped silicon Si:P- or boron doped silicon-germanium SiGe:B-based, for example.

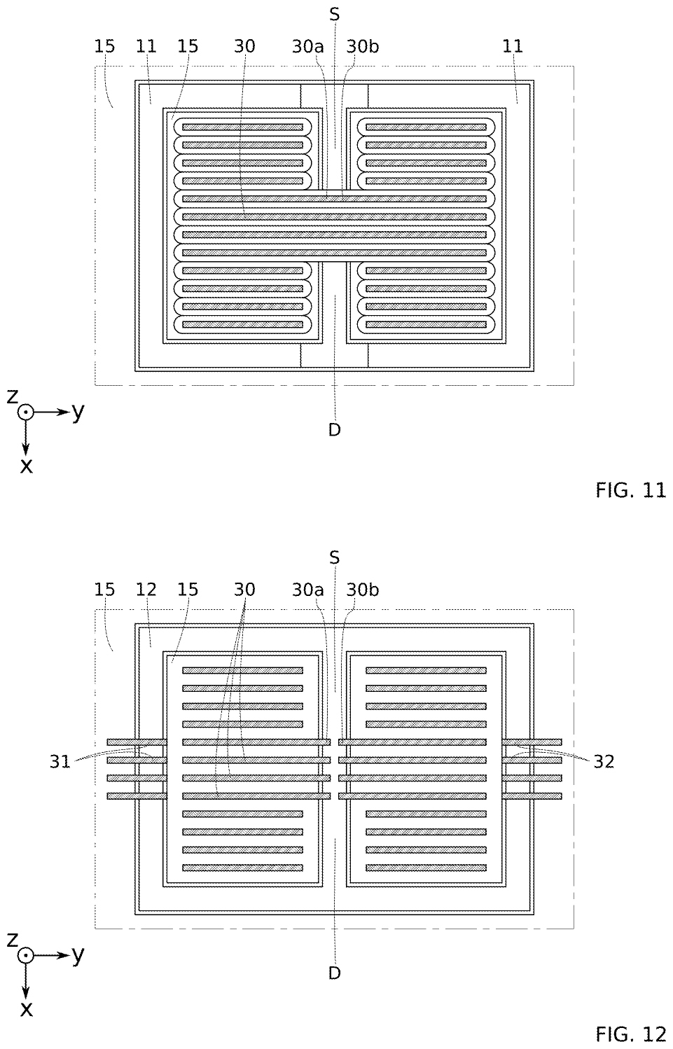

FIG. 11 illustrates a first embodiment of an electric insulation between the source and drain regions S, D. According to this embodiment, parts of the layer 12 located between the source and drain regions S, D, opposite the central bar C0 of the eight, are removed by etching thus exposing the underlying BOX 11.

FIG. 12 illustrates a second embodiment of an electric insulation between the source and drain regions S, D. According to this embodiment, secondary gates 31, 32 are formed at the same time as the vertical gates 30, above the parts of the layer 12 located between the source and drain regions S, D, opposite the central bar of the eight. A biasing of these secondary gates 31, 32 thus makes it possible to block the passage of the electric current between the source and drain regions S, D. The definition and the formation of the secondary gates 31, 32 is done advantageously during the definition and the formation of the vertical gates 30, without additional step in the method.

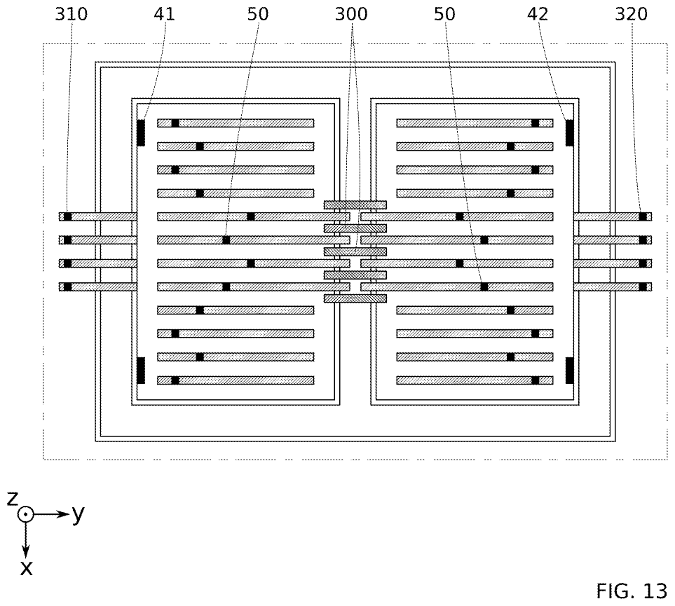

As illustrated in FIG. 13, after encapsulation of the vertical gates, all of the contacts of the device can be made. Contact vias 50 are thus made on the vertical gates 30. Contact vias 41 and 42 are thus made for the lateral gates G1, G2 respectively. Contact vias 310 and 320 are thus made for the secondary gates 31, 32 respectively. Exchange gates 300 are also made between the vertical gates, to enable an electrostatic modulation of the tunnel barrier height separating the adjacent quantum boxes along x.

In view of the description above, it clearly appears that the method proposed offers a particularly effective and versatile solution to form a lateral gate for an MOS device. The invention is not limited to the embodiments described above.

1. A semiconductive device comprising successively, stacked along a direction z,
a support layer,
an insulating layer, and
a semiconductive layer wherein an active zone is defined,
wherein the device further comprises a first lateral gate on a first edge of the active zone, configured to electrostatically control a distribution of charge carriers in the semiconductive layer perpendicularly to the direction z, and a vertical gate above the active zone, configured to electrostatically control the distribution of charge carriers in the semiconductive layer in the direction z,
the device further comprises a second lateral gate on a second edge of the active zone, configured to electrostatically control a distribution of charge carriers in the semiconductive layer perpendicularly to the direction z, said second lateral gate being electrically insulated with respect to the first lateral gate, and
the vertical gate is electrically insulated with respect to the first and second lateral gates, and the device further comprising a dielectric material encapsulating said first and second lateral gates.

2. The device according to claim 1, wherein the distribution of charge carriers is localized at a quantum dot, the device being a quantum device.

3. The device according to claim 2, wherein the first and second lateral gates and the vertical gate are metal or conductive at temperatures less than or equal to 50 mK.

4. The device according to claim 1, wherein the vertical gate comprises first and second parts not electrically connected to one another and partially covering the active zone.

5. The device according to claim 1, wherein the first and second lateral gates each have an L-shaped profile, in a plane parallel to the direction z.

6. The device according to claim 5, wherein the L-shaped profile of each of the first and second lateral gates is formed by a lateral portion of each of the first and second lateral gates, extending respectively on the first and the second edge of the active zone, and by a basal portion extending within the insulating layer, said basal portion extending under a plane passing through a lower face of the active zone.

7. The device according to claim 1, wherein the semiconductive layer has, projecting in the direction z, a shape comprising a first and a second closed contour which share a common section, and wherein the active zone is located in said common section, the first and second lateral gates being located respectively inside the first and second closed contours.

8. The device according to claim 7, further comprising secondary gates above the semiconductive layer on either side of the common section, said secondary gates being configured to electrically insulate source and drain regions located at the ends of the common section.

9. The device according to claim 1, further comprising several vertical gates, certain vertical gates covering at least partially the active zone, and certain other vertical gates not covering the active zone.

10. The device according to claim 1, further comprising at least one charge reservoir on either side of the active zone, in line with the vertical gate.

11. A method for producing a device comprising a metal-oxide-semiconductor-type structure formed from a stack successively comprising, in a direction z, a support layer, an insulating layer, and a semiconductive layer, the device further comprising at least one lateral gate configured to electrostatically control a distribution of charge carriers in the semiconductive layer perpendicularly to the direction z, said method comprising:
forming at least one trench passing through the semiconductive layer and extending up to into the insulating layer, said trench formation thus defining an active zone of the semiconductive layer, and exposing edges of said active zone,
forming a first dielectric barrier on each exposed edge of the active zone, said first dielectric barrier partially forming a flank of said at least one trench,
depositing an electrode layer on the flank of the at least one trench, and on a bottom of the at least one trench, said electrode layer having at least one lateral portion on the flank of the at least one trench, said lateral portion forming the lateral gate, and a basal portion on the bottom of the at least one trench,
filling the at least one trench with a dielectric material,
forming a second dielectric barrier on an upper face of the active zone and on an upper end of the lateral gate bordering the active zone, and
forming a vertical gate on the second dielectric barrier, above the active zone, configured to electrostatically control the distribution of charge carriers in the semiconductive layer in the direction z, so as to obtain the metal-oxide-semiconductor-type structure.

12. The method according to claim 11, further comprising, before the forming of the second dielectric barrier, partial etching the electrode layer lateral portion, configured to lower the upper end of the lateral gate under a plane passing through the upper face of the active zone.

13. The method according to claim 11, further comprising, after filling of the at least one trench and before formation of the second dielectric barrier, a planarization configured such that the upper end of the lateral gate is flat parallel to a plane passing through the upper face of the active zone.

14. The method according to claim 11, wherein the depositing of the electrode layer is further performed on a bottom of the at least one trench, said electrode layer having a basal portion on the bottom of the at least one trench in contact with the lateral portion on the flank of the at least one trench,
said method further comprising forming a contact via through the dielectric material configured to electrically contact the basal portion of the electrode layer.

15. The method according to claim 11, wherein the forming of at least one trench further comprises forming a first trench of a first side of the active zone and a second trench of a second side of the active zone, separated from the first trench, and wherein the depositing of the electrode layer forms, respectively in the first and second trenches, first and second lateral gates not electrically connected to one another.

16. The method according to claim 15, wherein the semiconductive layer has a shape comprising a first and a second closed contour, which share a common section, and wherein the active zone is located in said common section, the first and second lateral gates being located respectively inside the first and second closed contours,
said method further comprising an etching step, configured to cut the semiconductive layer on either side of the common section, so as to electrically insulate the source and drain regions located at the ends of the common section.

17. The method according to claim 15, wherein the semiconductive layer has a shape comprising a first and a second closed contour, which share a common section, and wherein the active zone is located in said common section, the first and second lateral gates being located respectively inside the first and second closed contours,
said method further comprising, during the forming of the vertical gate above the active zone, forming secondary gates above the semiconductive layer on either side of the common section, said secondary gates being configured to electrically insulate the source and drain regions located at the ends of the common section.
